(19) United States
(12) Patent Application Publication
(10) Pub. No.: US 2011/0018133 A1
(43) Pub. Date: Jan. 27, 2011

(54) ELECTRIC VIA WITH A ROUGH LATERAL SURFACE

(76) Inventors: HAMED CHAABOUNI, Grenoble (FR); Lionel Cadix, Grenoble (FR)

Correspondence Address: THE NOBLITT GROUP, PLLC, 4800 NORTH SCOTTSDALE ROAD, SUITE 6000, SCOTTSDALE, AZ, 85251, US

(21) Appl. No.: 12/839,897

(22) Filed: Jul. 20, 2010

(30) Foreign Application Priority Data
Jul. 21, 2009 (FR) 09/55053
Jul. 15, 2010 (EP) 10169734.0

(51) Int. Cl. H01L 29/06; H01L 21/768; H01L 23/48

(52) U.S. Cl. 257/739; 438/665; 257/E21.585; 257/E23.011; 257/E29.026

(57) ABSTRACT

A via connecting the front surface of a semiconductor substrate to its rear surface, this via having a rough lateral surface.

### BACKGROUND OF THE INVENTION

1. Field of the Invention

The present invention relates to an insulated electric connection between the front surface and the rear surface of a substrate, currently called via.

2. Discussion of the Related Art

Among the many fields of use of vias, chip stack devices may be mentioned. In such devices, it is provided to superpose semiconductor waters or chips above one another. This enables to increase the functions carried out by a device without increasing the occupied surface area.

In such devices, the connections between components of the different stages may be formed either by conventional wiring techniques, or by vias crossing the chip substrate.

An advantage of vias is the possibility of a collective manufacturing, conversely to wires which must be assembled individually. The other main advantages of vias over wires are a surface gain, and the possibility of a surface distribution of the inputs/outputs. Another advantage of the connection by vias is that such vias will currently be made in silicon wafers. The silicon wafers will then assembled in various ways, among which that described hereafter, to be eventually diced into individual chips. Such collective methods provide cost reductions. In the present description, chip assemblies will be mentioned, but it should be clear that the chips may be wafers, semiconductor wafers or elements of semiconductor wafers.

FIGS. 1A and 1B are side cross-section views illustrating steps of a method for forming a solid via having a diameter smaller than 10 μm, for example, on the order of from 0.5 to 10 μm. FIG. 1C is a top cross-section view along plane C-C of FIG. 1B and shows a section of the formed via.

A thinned-down semiconductor wafer or chip W1 is superposed to a semiconductor wafer or chip W2. Chips W1 and W2 are for example bonded together by molecular bonding. The thinning down of chip W1 may be performed before or after the bonding. Chips W1 and W2 are each formed in a semiconductor substrate, according to conventional methods. They especially each comprise active areas, in which components are formed, and a stack of conductive interconnect tracks, for example, copper tracks, connecting the components together and to the inputs-outputs. At the surface of chip W2, on the surface side common to chips W1 and W2, a conductive contact pad 1 is provided, for example corresponding to a copper portion of an upper interconnect level. Contact pad 1 is connected to a terminal of the chip by conductive tracks, not shown, to be able to be connected to a reference voltage in a subsequent electrolytic deposition step.

A hole 3, thoroughly crossing the substrate of chip W1, is formed in front of contact pad 1. Hole 3 may be bored by dry etch or chemical etch. The walls of hole 3 are insulated, for example, by deposition of a silicon oxide layer 5. The portion of insulating layer 5 covering, at the bottom of hole 3, contact pad 1, is removed to leave access to pad 1.

The assembly thus formed is dipped into an adapted conductive electrolytic solution, for example copper sulfide. Contact pad 1 is set to a negative voltage and forms a cathode. A copper anode, connected to a positive voltage, is dipped into the electrolytic solution. A current thus flows between the anode and the cathode. Copper progressively deposits by electrolysis on the cathode, thus filling hole 3. The electrolysis is interrupted when hole 3 is full, thus forming a cylindrical conductive via 7. A planarization step may further be provided to level the surface of via 7 after the electrolysis.

For diameters greater than a few μm, the forming of vias by electrolysis would be too long and too expensive to implement.

FIGS. 2A and 25 are side cross-section views illustrating steps of the forming of a hollow via having a diameter greater than 10 μm, for example, on the order of from 10 to 200 μm. FIG. 2C is a top cross-section via along plane C-C of FIG. 2B, and shows a cross-section of the formed via.

Semiconductor wafers or chips W1 and W2 are superposed as described hereabove. At the surface of chip W2, on the side of the surface common to chips W1 and W2, a conductive contact pad 11 is provided, for example corresponding to a copper portion of an upper interconnect level.

A hole 13 thoroughly crossing chip W1 is bored in front of pad 11. A sheath for insulating the walls of hole 13 is formed, for example, by deposition of a silicon oxide layer 15. The portion of insulating layer 15 covering contact pad 11 is removed to leave access to pad 11.

A conductive layer 17, for example, a copper layer, is formed by conformal deposition on the insulated walls and on the bottom of hole 13. Layer 17 forms a contact with pad 11 of chip W2.

The portions of layer 17 at the surface of chip W1 are removed to only keep the portion applied on the insulated walls and on the bottom of hole 13. The remaining portion of layer 17 thus forms a tubular via 17, which is ring-shaped in top view.

Via 17 is generally filled with a filling resin 19.

In operation, when vias conduct currents, they generate heat by Joule effect. This results in a rise of their temperature, that may cause damage or a decrease in the chip lifetime.

### SUMMARY OF THE INVENTION

An embodiment of the present invention overcomes all or part of the disadvantages of conventional vias.

An embodiment of the present invention provides a via structure enabling to limit the temperature rise of the via when it conducts a current.

Thus, an embodiment of the present invention provides a via connecting the front surface of a semiconductor substrate to the rear surface thereof, this via having a rough lateral surface.

According to an embodiment of the present invention, the rough lateral surface rests on a surface of a rough silicon layer.

According to an embodiment of the present invention, the rough silicon layer is a silicon layer with hemispherical grains.

According to an embodiment of the present invention, the above-mentioned via is insulated from the substrate by a thin layer of an electrically-insulating material.

According to an embodiment of the present invention, the electrically-insulating material is thermally conductive.

An embodiment of the present invention provides a method for manufacturing a via connecting the front, surface of a substrate to the rear surface thereof, comprising the successive steps of: a) boring a hole thoroughly crossing the substrate; b) covering the lateral walls of the hole with a polysilicon or amorphous silicon film; c) roughening the external surface of the film; and d) covering the external surface of the film and the bottom of the hole with an electrically-conductive material.

According to an embodiment of the present invention, step c) comprises the forming of silicon with hemispherical grains by double thermal anneal, under a controlled atmosphere containing silane, then in vacuum.

According to an embodiment of the present invention, each of the successive anneals is performed at a temperature ranging between 300° C. and 600° C.

According to an embodiment of the present invention, a step of forming of an thin layer of an electrically-insulating material is provided between steps c) and d).

According to an embodiment of the present invention, the electrically conductive material is copper.

The present invention will be discussed in detail in the following non-limiting description of specific embodiments in connection with the accompanying drawings.

### BRIEF DESCRIPTION OF THE DRAWINGS

FIGS. 1A and 18, previously described, are side cross-section views illustrating steps of the forming of a solid via having a diameter smaller than 10 μm;

FIG. 1C, previously described, is a top cross-section view of FIG. 1B showing a cross-section of a solid via;

FIGS. 2A and 28, previously described, are side cross-section views illustrating steps of the forming of a tubular via having a diameter greater than 10 μm;

FIG. 2C, previously described, is a top cross-section view of FIG. 2B showing a cross-section of a tubular via;

FIG. 3 is a side cross-section view very schematically showing an embodiment of a solid via having a diameter smaller than 10 μm;

FIGS. 4A to 4E are side cross-section views illustrating successive steps of an example of a method for forming the via of FIG. 3; and

FIG. 5 is a side cross-section view very schematically showing an embodiment of a hollow via having a diameter greater than 10 μm.

### DETAILED DESCRIPTION

For clarity, the same elements have been designated with the same reference numerals in the different drawings and, further, as usual in the representation of integrated circuits, the various drawings are not to scale.

The inventors have studied the dissipation of the heat generated in a via.

A first part of the heat propagates from the top and from the bottom of the via towards the chip interconnect tracks. However, the dissipation surface area provided by the interconnect tracks is small. Further, insulating layers, generally made of silicon oxide, are interposed between the successive interconnect levels. As a result, the heat dissipation via the interconnect tracks is low.

A second part of the heat is dissipated from the lateral external surface of the via through the insulating sheath, into the substrate bulk. However, the low thermal conductivity of the conductive sheath limits the heat dissipation in the substrate bulk.

The thermal exchanges between a Via and the bulk of the substrate that it crosses are here desired to be improved to decrease the temperature rise of the via.

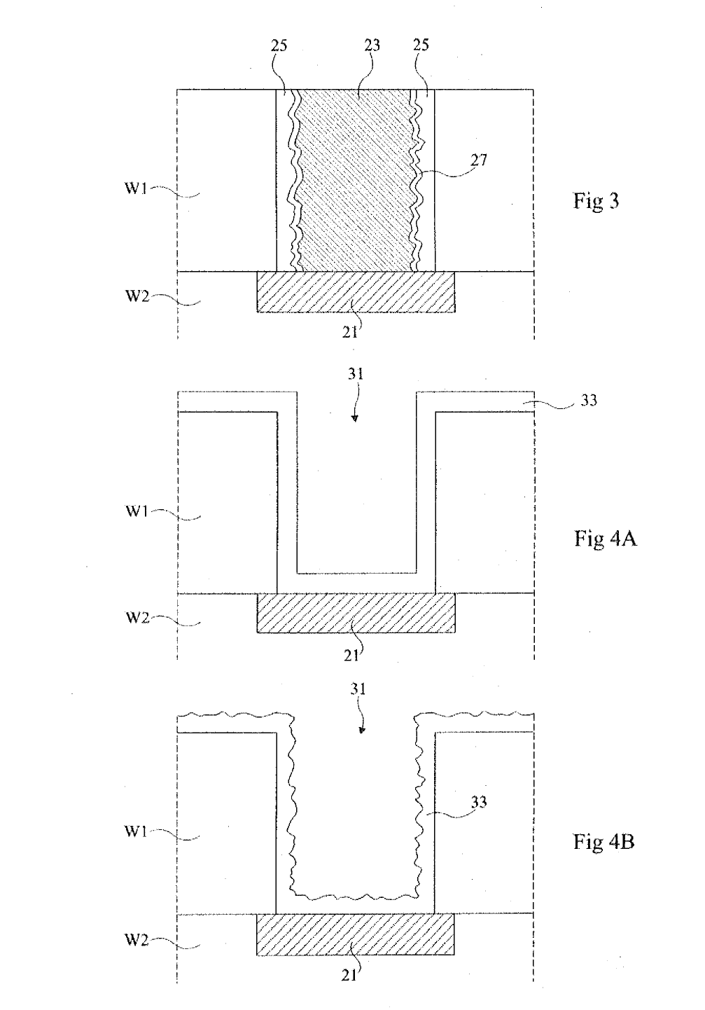

FIG. 3 is a side cross-section view very schematically illustrating an embodiment of a solid via having a diameter smaller than 10 μm.

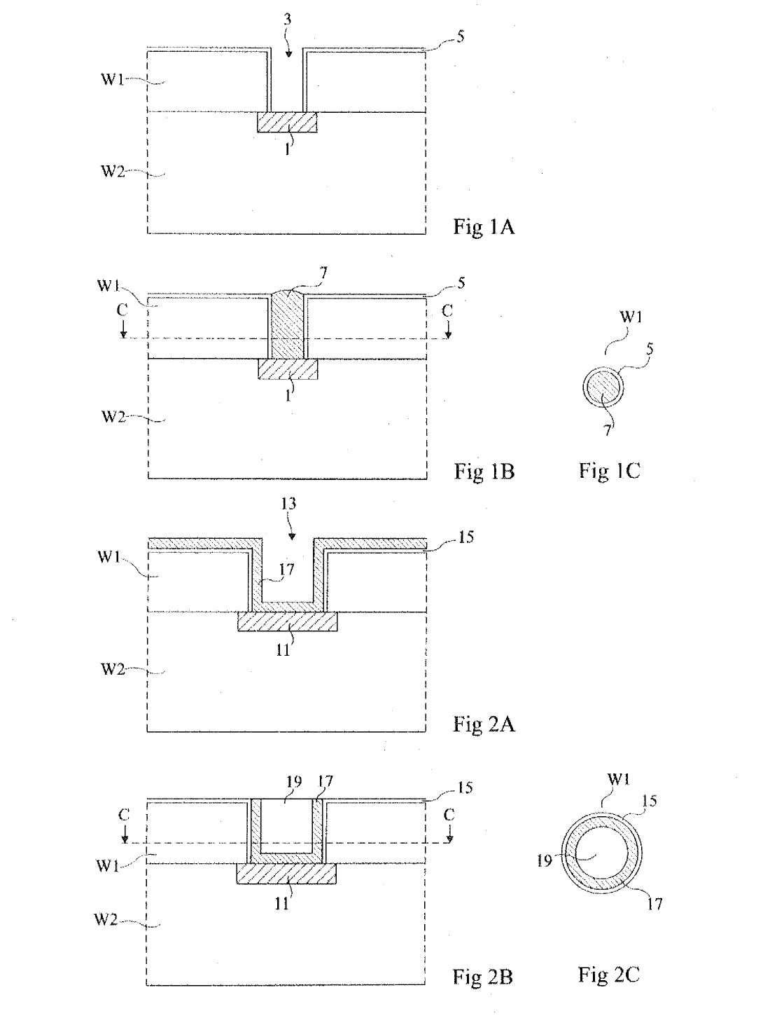

A thinned-down semiconductor wafer or chip W1 is superposed to a semiconductor wafer or chip W2 in the way described in relation with FIGS. 1A and 1B. At the level of the surface common to chips W1 and W2, a conductive contact pad 21 is provided, which for example corresponds to a copper portion of an upper interconnect level of chip W2. Contact pad 21 is connected to a terminal of the chip by conductive tracks, not shown, to be able to be connected to a reference voltage during an electrolysis step, described hereafter.

A solid via 23, formed of an electrically conductive material, thoroughly crosses chip W1 and forms a contact with pad 21 of chip W2.

A silicon ring 25 with a rough lateral internal surface extends around via 23. As will be explained in further detail hereafter, methods for depositing a silicon layer on a substrate and subsequently roughening the surface of this layer are known. Such methods for example result in the forming of a structure with hemispherical grains, currently designated as HSG-Si in the art, for “Hemispherical Grain Silicon”.

The lateral surface of via 23 rests on the rough lateral internal surface of ring 25. This means that the surface of the via is conformal to the rough surface of ring 25, exhibiting asperities or roughness in front of the wrinkles or recesses of the internal surface of ring 25, and wrinkles or recesses in front of the asperities or roughness of this surface. The lateral surface of solid via 23 is thus rough.

In the shown example, an insulating layer 27, for example formed of silicon oxide, insulates via 23 from the substrate.

A benefit of the provided embodiment is that the contact surface between the via with a rough lateral surface and the insulating silicon oxide layer is increased with respect to the case of conventional vias with a smooth lateral surface. This results in an increase in thermal exchanges between the via and the chip substrate. This limits the temperature rise of the via and the associated damage risks.

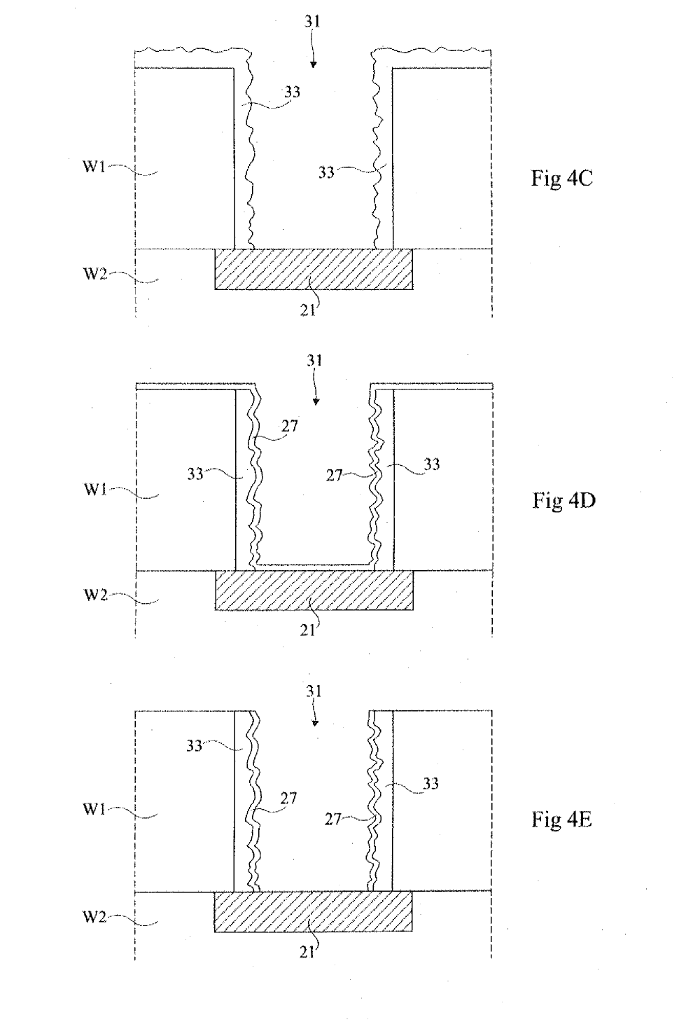

FIGS. 4A to 4E are side cross-section views illustrating successive steps of an example of the method for forming the via of FIG. 3.

FIG. 4A shows a semiconductor wafer or chip W1 placed against a semiconductor wafer or chip W2, as described in relation with FIGS. 1A and 1B. Chip W2 comprises, on the side of its surface common with chip W1, a conductive pad 21 in contact with chip W1.

A hole 31 thoroughly crossing chip W1 in front of contact pad 21 is bored, for example, by dry or chemical etching.

A silicon layer 33 is then deposited, covering the walls and the bottom of hole 31 as well as the surface of the substrate of chip W1. The deposition conditions of layer 33 must not result in damage to chips W1 and W2. As an example, a low-temperature and low-pressure deposition of an amorphous silicon or polysilicon layer may be performed.

FIG. 4B illustrates a step of roughening of silicon layer 33. A method resulting in the forming of hemispherical grains at the surface of layer 33 (HSG-Si) may for example be used. Such a method especially comprises a double thermal anneal of layer 33, under a controlled atmosphere for example containing silane (SiH₄), then in vacuum. Attention will be paid to properly selecting the anneal temperatures to avoid damaging chips W1 and W2. Anneals of a duration of a few tens of minutes at a temperature on the order of 450° C. may for example be carried out. This causes a surface unevenness of about 5 to 50

FIG. 4C illustrates a step of removal of the portions of rough layer 33 covering the surface of chip W1 and the bottom of hole 31. At the end of this step, only the portions of layer 33 covering the lateral walls of hole 31 are kept.

FIG. 4D illustrates a step of deposition of an insulating layer 27, for example, made of silicon oxide. As an example, layer 27 may be formed by conformal deposition or by thermal oxidation.

FIG. 4E illustrates a step of removal of the portions of insulating layer 27 covering the surface of chip W1 and the bottom of hole 31. At the end of this step, only the portions of layer 27 covering the lateral internal surface of rough ring 33 are kept.

The main conductive portion of via 23 shown in FIG. 3 is then formed during a step, not shown, for example, by filling of hole 31 with a conductive material by electrolytic deposition as described in relation with FIGS. 1A to 1C.

An embodiment of a solid via having a diameter smaller than 10 μm has been described herein. However, a hollow via having a diameter greater than a few μm, for example, on the order of from 10 to 200 μm, similar to the vias of the type described in relation with FIGS. 2A to 2C and with a rough lateral surface, may also be formed.

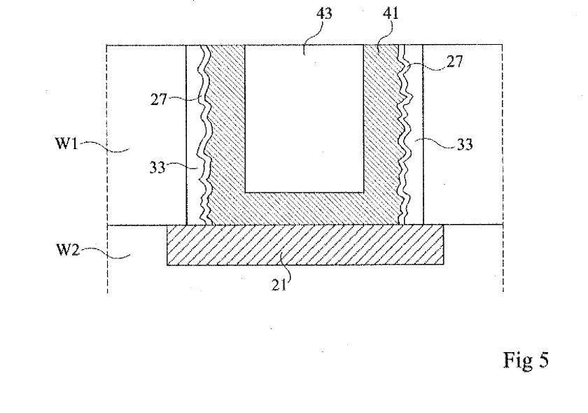

FIG. 5 is a side cross-section view schematically showing such a hollow via 41. Via 41 may be formed according to a method similar to that described in relation with FIGS. 4A to 4E, but for the fact that the main portion of the via is not formed by electrodeposition, but for example by conformal deposition, according to the embodiment of a hollow via described in relation with FIGS. 2A and 2B. Hole 31 may then be filled with a filling resin 43.

Specific embodiments of the present invention have been described. Various alterations and modifications will occur to those skilled in the art. In particular, the present invention is not limited to the sole method for forming a rough silicon layer described in relation with FIGS. 4A to 4E. Any other method capable of roughening the surface of a substrate may be used.

Further, in the case of a tubular via, to further increase the exchange surface area between the via and the substrate, a via having the shape of a festooned ring in cross-section view in a plane parallel to the front and rear surface of the substrate may be provided.

Moreover, the present description mentions copper vias and interconnection tracks. However, the present invention is not limited to this specific case. It will also be within the abilities of those skilled in the art to implement the desired operation by using other conductive metals or materials, for example, heavily-doped polysilicon, to form the conductive portion of the vias.

Further, the present invention is not limited to methods for forming the conductive portion of the via by electrodeposition or by conformal deposition, such as mentioned hereabove. As an example, the conductive portion of the via may be deposited by chemical vapor deposition of polysilicon. This silicon will be heavily doped to be made conductive.

Similarly, it will be within the abilities of those skilled in the art to implement the desired operation whatever the insulating materials used to form the various insulating layers mentioned in the description. In particular, the insulating sheath of the via is useless in the case of an insulating substrate. In the case of a conductive substrate, to further improve thermal exchanges between a via and the substrate, the sheath may be formed of a material which is electrically insulating but thermally conductive.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A via connecting the front surface of a semiconductor substrate (W1) to the rear surface thereof, this via having a rough lateral surface resting on a surface of a rough silicon layer.

2. The via of claim 1, wherein said rough silicon layer (is a silicon layer with hemispherical grains.

3. The via of claim 1, insulated from the substrate by a thin layer of an electrically-insulating material.

4. The via of claim 3, wherein said electrically-insulating material is thermally conductive.

5. A Method for manufacturing a via connecting the front surface of a substrate to the rear surface thereof, comprising the successive steps of:
a) boring a hole thoroughly crossing the substrate (W1);
b) covering the lateral walls of the hole with a polysilicon or amorphous silicon film;
c) roughening the external surface of the film; and
d) covering the external surface of the film and the bottom of the hole with an electrically-conductive material.

6. The method of claim 5, wherein step c) comprises the forming of silicon with hemispherical grains by double thermal anneal, under a controlled atmosphere containing silane, then in vacuum.

7. The method of claim 5, wherein each of the successive anneals is performed at a temperature ranging between 300° C. and 600° C.

8. The method of claim 5, comprising, between steps c) and d), a step of forming of an thin layer of an electrically-insulating material.

9. The method of claim 5, wherein the electrically-conductive material is copper.
